(19) United States
(12) Patent Application Publication
(10) Pub. No.: US 2014/0284092 A1
(43) Pub. Date: Sep. 25, 2014

(54) SPLIT PAD FOR CIRCUIT BOARD

(71) Applicants: Jing Bai, Tianjin (CN); Yin Guo, Tianjin (CN); Shayan Zhang, Austin, TX (US); Yanyan Zhang, Tianjin (CN)

(72) Inventors: Jing Bai, Tianjin (CN); Yin Guo, Tianjin (CN); Shayan Zhang, Austin, TX (US); Yanyan Zhang, Tianjin (CN)

(21) Appl. No.: 14/178,303

(22) Filed: Feb. 12, 2014

(30) Foreign Application Priority Data
Mar. 25, 2013 (CN) 201310209342.X

(51) Int. Cl. H05K 1/02; H05K 1/11

(52) U.S. Cl. CPC H05K 1/0296; H05K 1/117; H05K 1/115
USPC 174/262; 174/250

(57) ABSTRACT

An electronic device such as a circuit board has a contact pad for connection to a contact of a component, and a pad portion interconnection. The contact pad has physically separate pad portions. The pad portion interconnection electrically connects the pad portions of the contact pad, independently of any mounted connection on the pad portions. Providing multiple pad portions for a single contact pad allows the contact pad to function even if one of the pad portions is damaged such as by peeling off. An example application is an EMC (Electromagnetic Compatibility) and/or ESD (Electro-Static Discharge) test circuit board.

### FIELD OF THE INVENTION

The present invention relates to circuit boards and, more particularly, to a contact pad for a circuit board.

In some applications it is desirable to remove an attached component, such as a semiconductor chip, from a circuit board and replace it with a replacement component. This may involve unsoldering and removal of the attached component and positioning and soldering the replacement component to the same contacts of the circuit board. Such a process is often performed with circuit boards used for testing electronic devices. After a first component is tested, it may be removed from the test board, and a second component attached in place of the first component, in order to test the second component. An example of such a circuit board is an EMC (Electromagnetic Compatibility) test circuit. However, the contacts of the circuit board can be damaged from continual replacement of the attached component. For example, the contact pads can peel off.

There are socket types that allow semiconductor chips or components to be replaced without soldering but in applications like EMC and ESD (Electro-Static Discharge), these reusable multi-insertion sockets can be difficult to use due to test insertion difficulties and sensitivity of the test results on added capacitive load from the socket.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 is a top plan view of an example of contact pads for mounting a component in accordance with an embodiment of the present invention;

FIG. 2 is an enlarged top plan view of one of the contact pads of FIG. 1;

FIG. 3 is a side view of the contact pad of FIG. 2 along direction A;

FIG. 4 schematically shows an example of a contact of a component connected to the contact pad of FIG. 2;

FIG. 5 schematically shows an example of a contact of a component connected to the contact pad of FIG. 2;

FIG. 6 schematically shows an example of the connection method of a contact pad;

FIG. 7 schematically shows an example of the connection method of a contact pad;

FIG. 8 schematically shows an example of the connection method of a contact pad;

FIG. 9 schematically shows a layer structure of a circuit board according to an example;

FIGS. 10A, 10B and 10C schematically show examples of a contact of a component connected to a contact pad;

FIGS. 10D, 10E and 10F schematically show examples of a contact of a component connected to a contact pad; and

FIG. 11 is a flow chart illustrating an example of a method of using a circuit board including a contact pad of the present invention.

### DETAILED DESCRIPTION OF THE PREFERRED EMBODIMENTS

Illustrated embodiments of the present invention may for the most part, be implemented using electronic components and circuits known to those skilled in the art. Accordingly, details will not be explained in any greater extent than that considered necessary as illustrated above, for the understanding and appreciation of the underlying concepts of the present invention and in order not to obfuscate or distract from the teachings of the present invention.

A circuit board may have contact pads, for electrical connection of a component, such as a chip (packaged semiconductor die), to the circuit board. The contact pads also may be used for mechanical attachment of the component. An example of such a pad is a pad for use in surface mount technology (SMT) that may be electrically and mechanically bonded to a contact of the component by solder.

In some cases, removal of an attached component also results in removal of the contact pad, e.g. due to the pad being peeled off from the circuit board. The removal of a contact pad will often result in the circuit board becoming unusable. Repair of a circuit board damaged in this way is unlikely to be practical or economical, and so the entire circuit board must normally be replaced following removal of a contact pad.

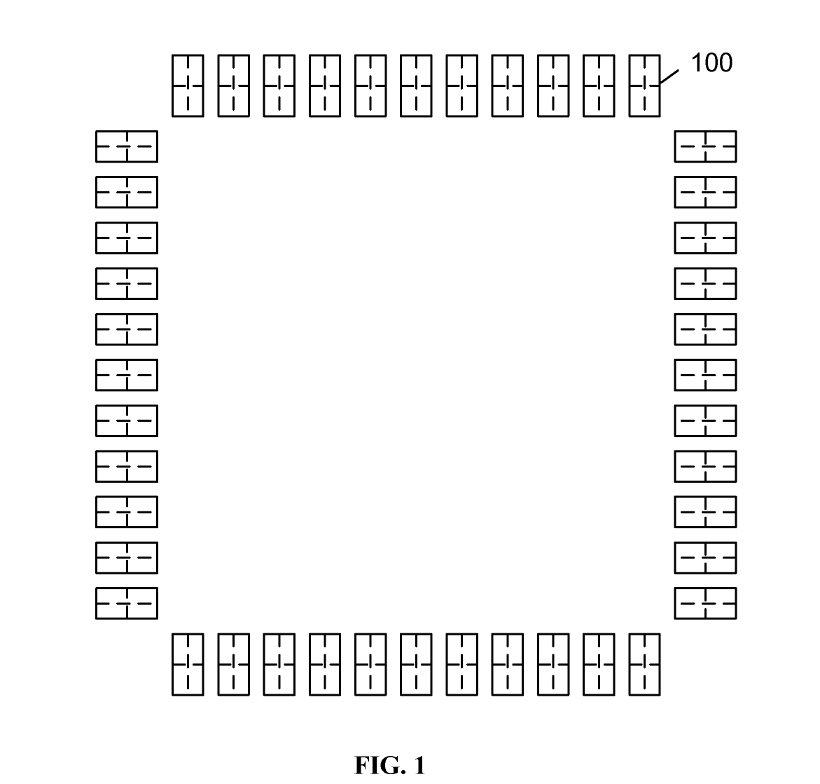

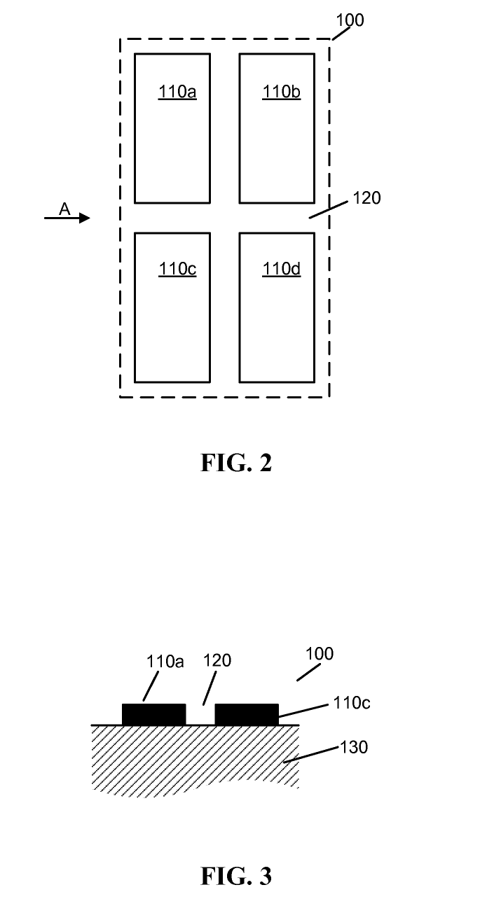

FIG. 1 shows contact pads 100 for mounting a component, such as a chip, according to an example. FIG. 2 shows the contact pads 100 in more detail. Each of the contact pads 100 is arranged to bond to a respective electrical contact of a component or device to be attached to the circuit board. For example, the electrical contact may be a contact pin of a chip.

Each of the contact pads 100 comprises a plurality of pad portions 110a-110d that are physically separate from each other. In the example shown in FIG. 2, the contact pad 100 has four pad portions 110a-110d. The pad portions 110a-110d are physically separated from each other by an insulator, non-conductive openings or an air gap 120. The physical separation may be such that peeling of one of the pad portions 110a-110d does not affect the remaining pad portions 110a-110d. In some examples, each of the pad portions is separated from any adjacent pad portions of the contact pad by non-conductive openings having widths greater than or equal to 4 mil (101.6 μm) and less than or equal to 30 mil (762 μm).

In the example of FIG. 2, there are four pad portions 110a-110d in the contact pad 100. In this example, the pad portions are arranged in 2 rows and 2 columns. The pad portions 110a-110d preferably are electrically connected to each other, such that an electrical connection to any subset of the pad portions 110a-110d is essentially electrically equivalent to a connection to all of the pad portions 110a-110d.

FIG. 3 shows a cross-section section along direction A (shown in FIG. 2). In this example, the pad portions 110a-110d are separated by non-conductive openings 120. As can be seen, the pad portions 110 are disposed on a surface a circuit board 130.

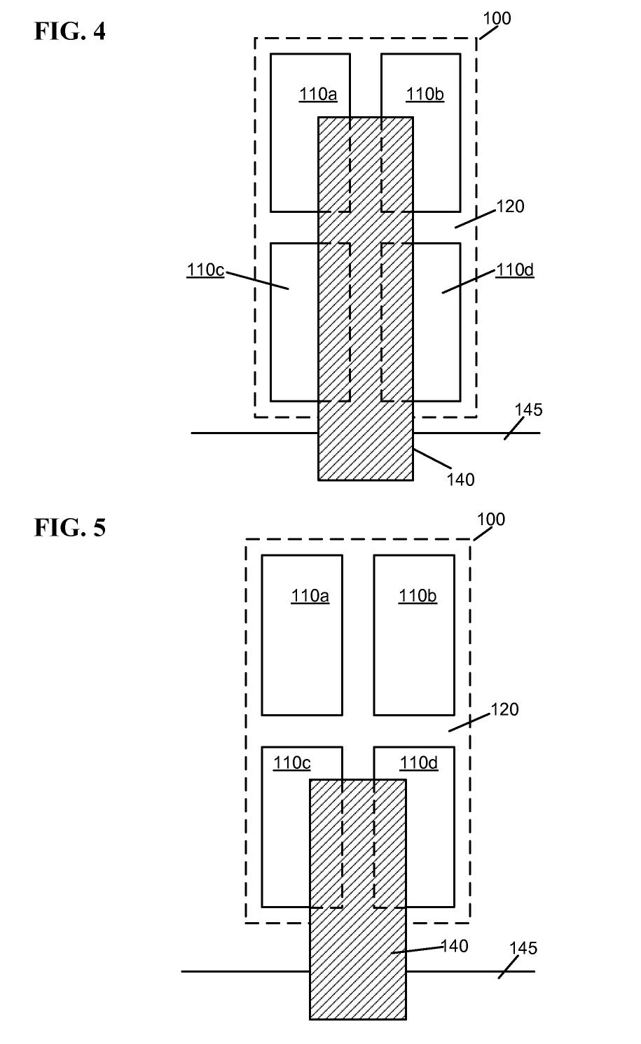

FIG. 4 illustrates an electrical contact 140 for a component 145, such as a contact pin of a chip, connected to the contact pad 100. The contact 140 may be connected to the contact pad 100 by solder (not shown). As can be seen in FIG. 4, the contact 140 is connected to all of the pad portions 110a-110d. FIG. 5 shows an alternative arrangement, in which the contact 140 is connected to only two of the pad portions 110a-110d of the contact pad 100. In some examples, the contact 140 may be connected to a single pad portion 110a-110d.

As the pad portions 110a-110d are physically separated, if one of the pad portions 110a-110d is compromised, such as by peeling off due to repetitive component placement and removal, this will not directly affect the remaining pad portions 110a-110d, and also the contact pad 100 will still be functional. That is, as the pad portions 110 are electrically connected, when one or more of the pad portions 110 is removed, the remaining pad portions 110 continue to provide an electrical connection to the electrical contact 140 of the component 145. As will be discussed in more detail below, the electrical connection between the pad portions 110 may be provided by a pad portion interconnection. The pad portion interconnection may include one or more of a trace, a via, and a conductive shape. Where the pad portion includes vias, the vias may be electrically connected with each other by a via connector. The via connector may be a conductive shape, for example.

In some examples, the contact pad 100 is formed on a first layer of the circuit board 130. The circuit board 130 may have multiple layers. In some examples, the first layer is a bottom layer of the circuit board 130. In some examples, the first layer may be referred to as a chip mounting layer.

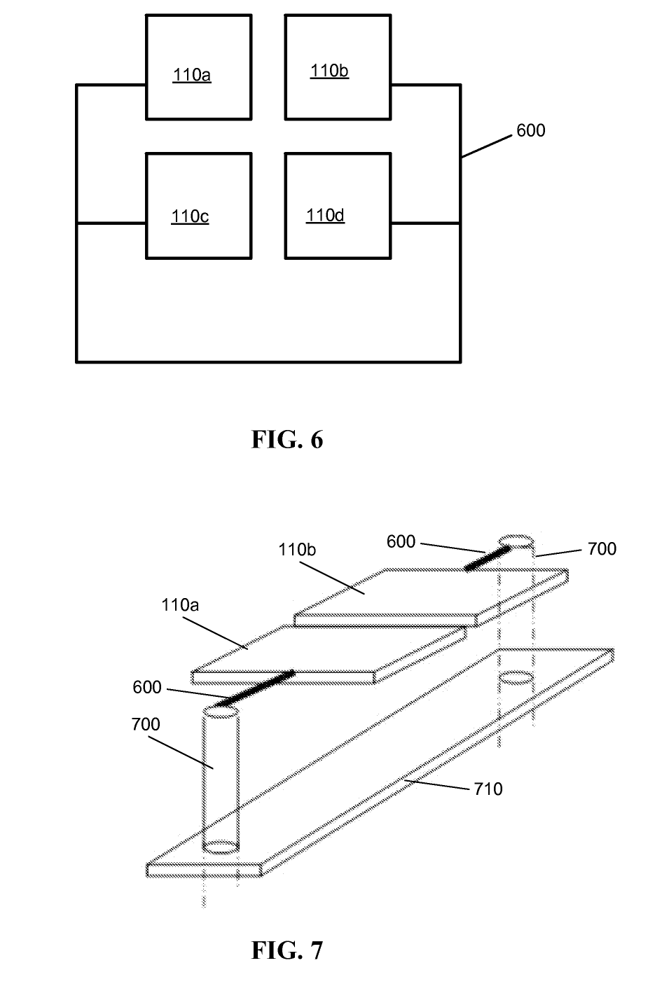

Referring now to FIG. 6, the pad portions 110 may be connected directly to each other by one or more traces 600. Here “connected directly” means that the pad portions 110 are connected electrically by a trace without requiring additional elements (such as vias) to electrically connect the pad portions. The traces 600 may be arranged to avoid the separation areas 120 between the pad portions 110a-d. This may reduce the likelihood of the trace 600 being removed when a pad portion 110a-d is removed.

FIG. 7 shows an arrangement in which the pad portions 110a-110b are connected by traces 600, vias 700 and a conductive shape 710. In FIG. 7 two pad portions 110a-b are shown for clarity, but the other pad portions 110 also are electrically connected to a conductive shape such as the conductive shape 710 by vias 700. The vias 700 are electrically conductive, and may be metal vias. The conductive shape also may be formed of metal.

Each pad portion 110a-b is electrically connected to a respective via 700 by a respective trace 600. The vias 700 are electrically connected to each other by the conductive shape 710. In this example, the pad portions 110 are connected directly to the respective trace 600, and the traces 600 are connected directly to the respective vias 700, which in turn are each connected directly to the conductive shape 710.

In the arrangement of FIG. 7, the pad portions 110a-110b are provided at a first layer and the conductive shape 710 is provided at a second layer. The substrate(s) of the circuit board are not shown in FIG. 7. The second layer preferably is a physically different layer from the first layer. There may be one or more layers of substrate between the first and second layers. The vias 700 penetrate one or more of the substrate layer(s). The vias may be through-hole or bind-hole, as are known in the art.

The conductive shape 710 may be any shape that electrically connects each of the vias 700 associated with a particular contact pad 100. In some examples the conductive shape 710 does not contact vias associated with other contact pads for the same component. And in some arrangements, the traces 600 may avoid areas between the pad portions 110a-d.

By electrically connecting the pad portions 110a-d using vias 700 it is possible to limit an amount of peeling that occurs when a pad portion 110a-d is removed. For example, where the pad portions 110a-d are connected by a trace, peeling of one pad portion 110a-d may result in peeling of a trace connected to the pad portion 110a-d, and in turn lead to peeling of a further pad portion connected to the trace. As vias 700 cannot be peeled, it is possible to prevent peeling of one pad portion 110a-d from causing peeling of another pad portion 110a-d.

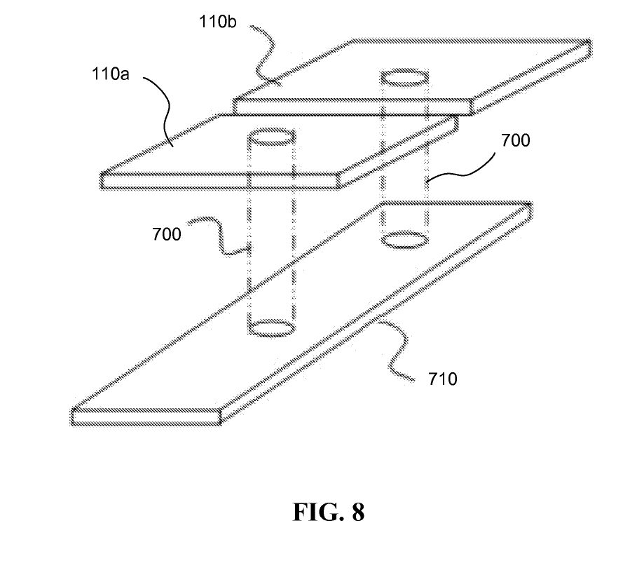

FIG. 8 shows an arrangement in which the pads portions 110a-110b are connected by respective vias 700 and a conductive shape 710. As with FIG. 7, two pad portions 110a-b are shown, but additional pad portions could be provided. In the example of FIG. 8, the vias 700 are connected directly to the pad portions 110a-110b, and the vias 700 are connected directly to the conductive shape 710. That is, in this arrangement there is no trace connected to the pad portions 110a-b, and so when a pad portion 110a-b is removed, there is no trace that also will be removed.

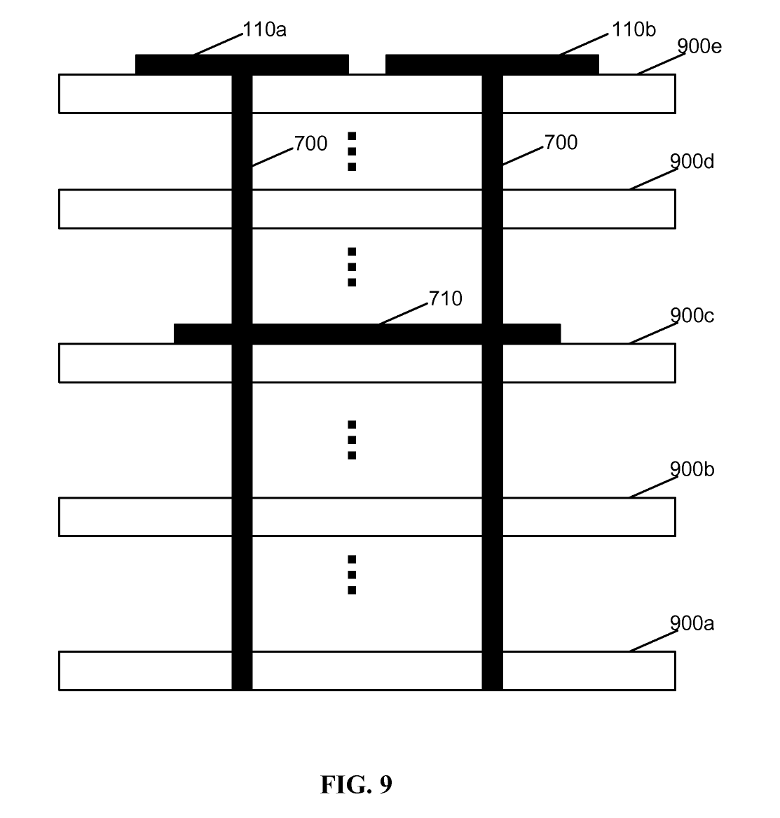

FIG. 9 shows a layer structure according to an example of the arrangement of FIG. 8. According to this example, the pad portions 110a-110d are provided on a first layer 900e (e.g., a chip mounting layer) of a circuit board. In some examples the contact pads 100 may be the only electrical components on the first layer 900e (excluding the component mounted to the contact pads 100, when mounted). A third layer 900a (e.g. a component mounting layer) may be provided on an opposite side of the circuit board. The third layer 900a may have electrical components mounted thereon.

The circuit board may include a plurality of substrate layers, forming the first and third layers 900e, 900a. Other layers also may be formed by the substrate layers. The vias 700 are in electrical contact with the respective pad portions 110a-d. The vias 700 penetrate the first layer 900e, and possibly other layers, to provide an electrically conductive connection between the pad portions 110a-d and feature(s) (e.g., electronic components, conductive paths, etc.) on one or more layers other than the first layer 900e.

In the example of FIG. 9, the substrate layers also form a second layer 900c (e.g., a connector layer). The second layer 900c may include an electrically conductive portion, such as conductive shape 710 electrically connecting the vias 700 with each other. In the example of FIG. 9, all of the vias 700 associated with a single contact pad 100 are mutually electrically connected by the conductive shape 710. In alternative examples, the conductive portion (e.g., the conductive shape 710) may electrically connect only a subset of the vias 700, the remaining vias being interconnected by other conductive portions on one or more other layers to result in all of the vias associated with the contact pad 100 being mutually electrically connected.

One or more substrate layers 900d may be provided between the first layer 900e (i.e. the layer having the contact pad 100) and the second layer 900c.

Impedance may be reduced by having the first layer 900e close to the second layer 900c. In some examples the first layer 900e and the second layer 900c may be adjacent (i.e. have no substrate layers between them), and so a low impedance may be achieved.

One or more additional substrate layers 900b may be provided between the second layer 900c and the third layer 900a. In some examples, no layers are provided between the second layer 900c and the third layer 900a. In some examples, the second and third layers 900c, 900a are formed on opposite sides of the same substrate layer. In some examples, the vias 700 may be connected at the third layer 900a. This may reduce an effect on the electrical characteristics of the contact pads 100 and help to ensure the electrical connectivity of the pad portions 110a-d.

In some examples, the vias 700 may terminate at the second layer 900c, i.e. the vias pass between the first layer 900e and the second layer 900c, but do not pass beyond the second layer 900c. In some examples (such as that shown in FIG. 9) the vias 700 may continue beyond the second layer 900c, and extend to the third layer 900a, or to the surface (e.g., the component mounting surface) of the circuit board opposite the surface having the contact pad 100.

In some examples, one or more electrical components mounted on the third layer 900a may be connected electrically with the pad portions 110a-d.

Other arrangements are possible. For example, the vias 700 could be electrically connected to each other by one or more traces, or the vias 700 could be electrically connected to the conductive shape 710 by traces 600 on the second layer 900c.

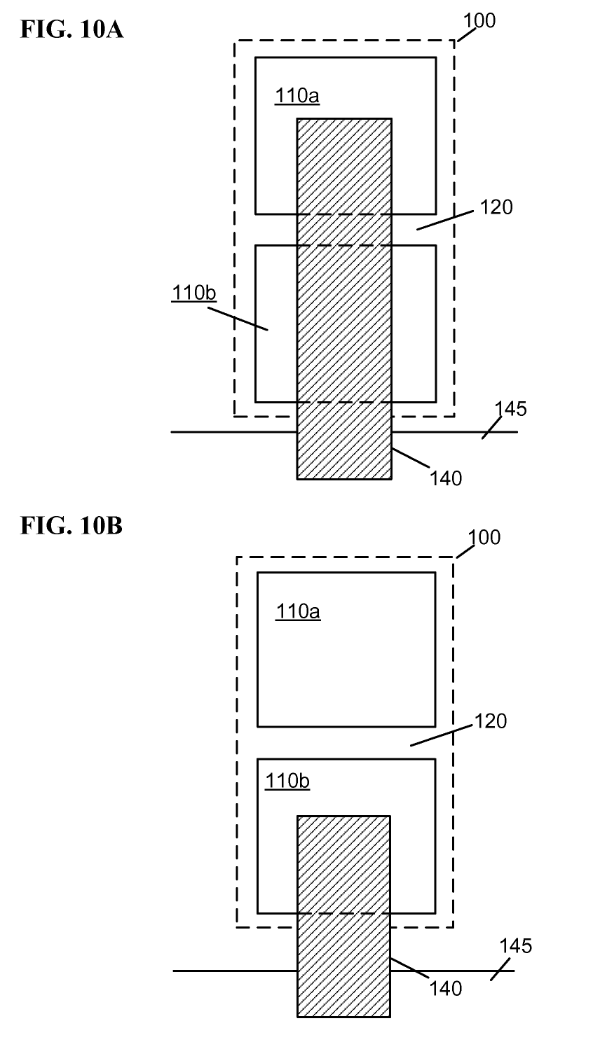

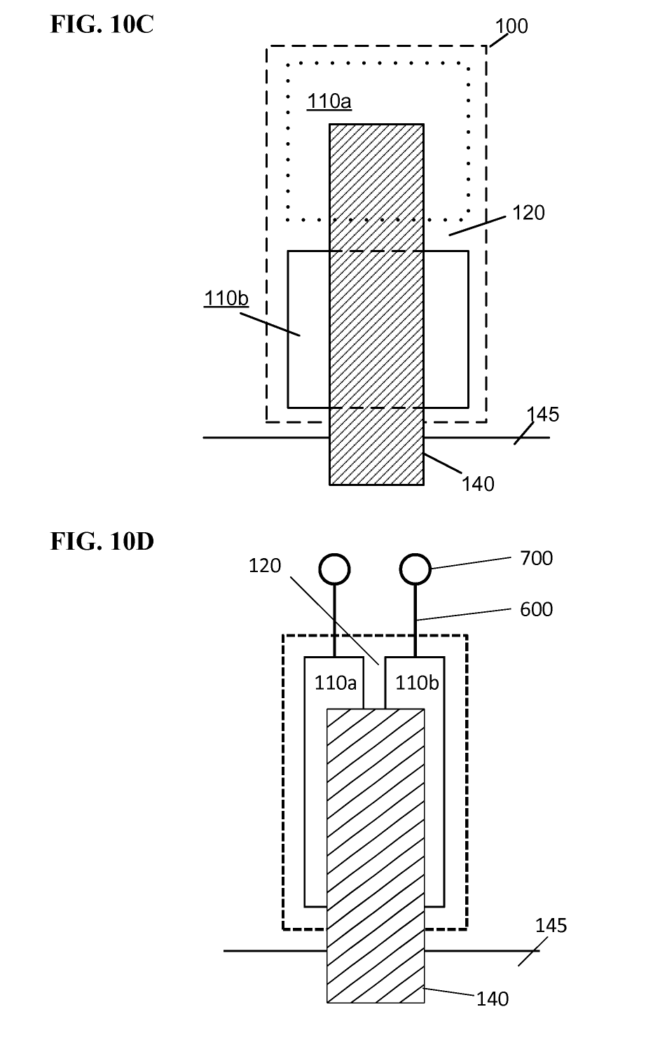

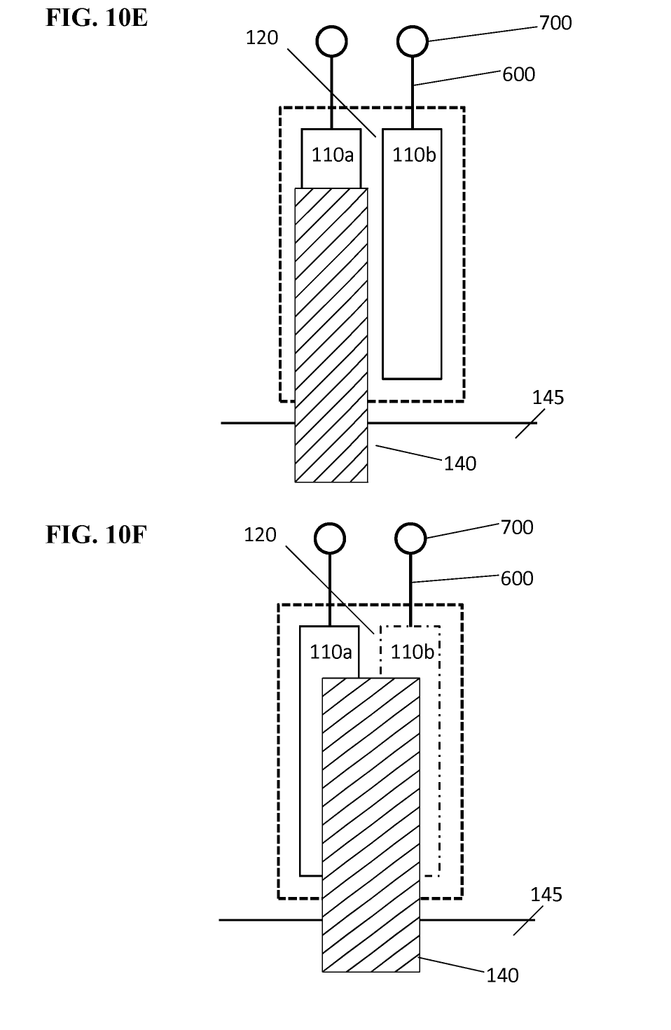

FIG. 10A shows an example of a contact pad 100 having two pad portions 110a-b arranged with one of the pad portions 110b being proximate to an edge of the component 145 and the other of the pad portions 110a being separated from the edge of the component 145 by the pad portion 110b. In FIG. 10A, both pad portions 110a-b are attached to a contact 140 of the component 145. Similar elements to those of FIG. 4 are given corresponding reference signs in FIG. 10A.

FIG. 10B shows an example of the contact pad 100 of FIG. 10A with only the pad portion 110b attached to the contact 140 of the component 145. FIG. 10C shows an example similar to that of FIG. 10A, except that the pad portion 110a has been removed (e.g. peeled off from over use) so even though the contact 140 of the component 145 extends over the pad portion 110a (shown in outline), the contact 140 actually only is electrically connected to the pad portion 110b.

FIG. 10D shows another example of a contact pad having two pad portions 110a-b arranged side-by-side with respect to an edge of a component 145. That is, both pad portions 110a and 110b are proximate to the edge of the component 145. In this example, both pad portions 110a-b are attached to a contact 140 of the component 145. Similar elements to those of FIG. 4 for pads arrangement and FIGS. 6 and 7 for via 700 and trace 600 attachments are given corresponding reference signs in FIG. 10D. FIG. 10E shows an example of the component contact 140 being connected or in contact with only the pad portion 110a and not in electrical contact with the pad portion 110b. FIG. 10F shows an example similar to that of FIG. 10D, in which one of the pad portions 110b has been removed and thus the contact 140 of the component 145 is attached to only the pad portion 110a even though it also overlies the space that was occupied by the pad portion 110b (shown as a dotted line).

In some examples, each of the pad portions 110a-d are substantially electrically homogeneous, having essentially the same conductance to the via connector (e.g., shape 710). This may improve consistency when different pads are used following removal of a mounted component and mounting of a new component.

The number, shape and arrangement of pad portions is not particularly limited. In some examples the pad portions are arranged in rows and columns, e.g. in an N×M array (where N and M are natural numbers and N×M≧2). For example, the contact pad 100 may have N×M pad portions 110a-d arranged in N rows and M columns, where N≧2 and M≧1, or N≧1 and M≧2. In the example of FIG. 2, N=M=2. In the example of FIGS. 10a and b, N=2 and M=1. In another example of FIGS. 10D and 10F, N=1 and M=2.

Arranging the pad portions 110a-d in rows and columns permits a high ratio between a maximum area of the individual pad portions 110a-d and the area of the contact pad 100. Such arrangements may also allow easy and reliable soldering of components on the contact pad 100.

In some examples at least one pad portion 110a-d of the contact pad 100 has sufficient area to bond an electrical contact 140 (such as a pin of a chip). In some examples, each pad portion 110a-d has sufficient area to bond an electrical contact 140. In some examples an adjacent pair of pad portions 110a-d together has an area sufficient for bonding an electrical contact. In some examples, a combined area of the pad portions 110a-d of the contact pad 100 is sufficient for bonding an electrical contact 140. Herein bonding may entail forming an electrical and a physical bond, e.g. by soldering. In some examples, the pad portions each have a width greater than or equal to 10 mil (254 μm). In some examples the combined area of the pad portions 110a-d is greater than an area of a contact footprint of a contact 140. In some examples an area of the contact pad 100 (including pad portions 110a-d and insulating portions 120 between the pad portions 100a-d) is larger than a contact footprint of a contact 140.

In some examples, all of the pad portions 110a-d in the area of the contact pad 100 are electrically interconnected. In some examples the pad portions 110a-d form the entire contact pad 100. In some examples, a pair of the electrically interconnected pad portions 110a-d are adjacent to each other, such that pair of pad portions 110a-d are separated only by a non-conductive opening, an air gap or an insulator 120 between the pad portions 110a-d, and no conductor is provided between the pair of pad portions 100a-d (except possibly conductor associated with mounting a component on the contact pad 100, such as a contact 140 of a component 145 mounted on the contact pad 100, or solder for mounting the pin of the component). In some examples each pad portion 110a-d is adjacent to at least one other pad portion 110a-d.

In the examples above an electrical connection between vias is formed by a conductive shape. More generally a via connector may be any structure suitable for forming an electrically conductive connection between the vias.

In some examples, the contact pad 100, described above, may be provided on a test board, such as a board for testing a chip attached to the contact pad 100. In some examples, the contact pad 100 is provided on an EMC test board.

Where there is a plurality of contact pads 100, each of the contact pads 100 may have a structure similar to the contact pads described above. Contact pads 100 on a circuit board may have the same arrangement of pad portions 110a-d, or different arrangements of pad portions 110a-d.

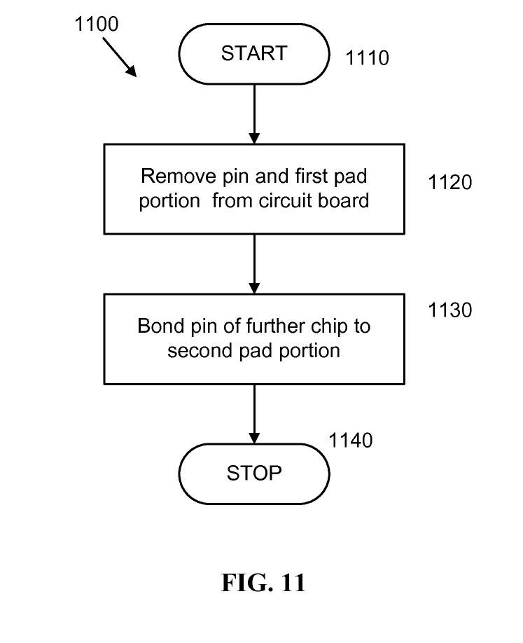

FIG. 11 is a flow chart illustrating an example of a method of using a circuit board as described herein. The method begins at 1110, and at 1120 a contact 140 (e.g. a pin) of a first component 145 (e.g. a chip) is removed from the circuit board to which it was previously bonded. The removal of the contact also causes removal of a pad portion 110a-d from the circuit board. At step 1130, a contact 140 of a second component is bonded or attached to a second pad portion 110a-d of the chip. The method terminates at step 1140.

According to embodiments described above, if a pad portion 110a-d is removed, e.g. by peeling during removal of a component attached to the pad portion 110a-d, the circuit board may still be used by attaching a subsequent component to the remaining pad portions 110a-d.

According to some examples, a circuit board having a contact pad 100 as described above may have improved reusability, and improved endurance against frequent chip replacement. The circuit board may have an increased lifetime (in terms of number of times a component may be removed and reattached), which may lead to a reduction in the frequency with which replacement circuit boards are necessary. Examples provide a simple structure that does not compromise electrical performance of the circuit board.

In the foregoing specification, the invention has been described with reference to specific examples of embodiments of the invention. It will, however, be evident that various modifications and changes may be made therein without departing from the broader spirit and scope of the invention as set forth in the appended claims.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. An electronic device, comprising:
a contact pad for connection to a contact of a component, wherein the contact pad includes a plurality of physically separate pad portions; and
a pad portion interconnection that electrically connects the plurality of pad portions, independently of any mounted connection on the pad portions.

2. The device claim 1, wherein the plurality of pad portions comprises N×M pad portions, the pad portions arranged in N rows and M columns.

3. The device of claim 1, wherein N≧2 and M≧1, or N≧1 and M≧2.

4. The device of claim 1, wherein the component comprises a chip and the contact pad is a contact pad for surface mount connection to a pin of the chip.

5. The device of claim 4, wherein:
an area of at least one of the pad portions is sufficient for bonding the pin of the chip, or
an adjacent pair of pad portions together have an area sufficient for bonding the pin of the chip, or
a combined area of the pad portions is sufficient for bonding the pin of the chip.

6. The device claim 4, wherein an area of a first pad portion of the plurality of interconnected pad portions is sufficient for bonding the pin of the chip.

7. The device of claim 1, wherein each of the pad portions is separated from any adjacent pad portions of the contact pad by non-conductive openings having widths greater than or equal to 101.6 μm and less than or equal to 762 μm.

8. The device of claim 1, wherein the pad portions each have a width greater than or equal to 254 μm.

9. The device of claim 1, wherein the pad portion interconnection comprises a plurality of vias and a via connector, wherein
each of the pad portions of the contact pad is electrically connected to a respective via of the plurality of vias,
the contact pad is at a first layer of the electronic device, and
the via connector electrically connects the plurality of vias, the via connector is in a second layer of the electronic device, and the second layer is different from the first layer.

10. The device of claim 9, wherein the first and second layers are physically different layers of the electronic device.

11. The device of claim 9, wherein the first and second layers are adjacent layers.

12. The device of claim 9, further comprising a trace on the same layer as the contact pad, the trace electrically connecting a pad portion of the plurality of pad portions with the respective via.

13. The device of claim 1, wherein the electrically interconnected pad portions form the entire contact pad.

14. The device of claim 1, wherein the electrically interconnected pad portions are adjacent to each other.

15. The device of claim 1, wherein the electrically interconnected pad portions have only insulator between them at the surface of the electronic device.

16. The device of claim 1, wherein the electronic device is an electromagnetic compatibility test board.

17. A circuit board, comprising:
a first layer having a contact pad arranged for connection to corresponding contact of an electronic component, wherein the contact pad includes a plurality of physically separate pad portions;
a plurality of vias electrically connected to respective ones of the pad portions and extending generally perpendicular to the first layer;
a second layer, planar with and separate from the first layer, the second layer including a conductive shape that electrically connects the plurality of vias.

18. The circuit board of claim 17, further comprising a plurality of traces respectively connecting the plurality of pad portions with the respective corresponding vias.

19. The circuit board of claim 18, wherein the plurality of traces are located in the first layer.

20. The circuit board of claim 18, wherein the plurality of pad portions are separated from each other with an insulator.
